(19) United States
(12) Patent Application Publication
(10) Pub. No.: US 2026/0100722 A1
(43) Pub. Date: Apr. 9, 2026

(54) METHODS, SYSTEMS, AND APPARATUS FOR PROTOGRAPH-BASED LOW DENSITY PARITY CHECK CODING

(71) Applicant: Huawei Technologies Co., Ltd., Shenzhen (CN)

(72) Inventors: Huazi Zhang, Hangzhou (CN); Wen Tong, Ottawa (CA); Jianglei Ma, Ottawa (CA); Yiqun Ge, Ottawa (CA); Xiaoyan Bi, Shanghai (CN); Jun Wang, Hangzhou (CN)

(21) Appl. No.: 19/402,542

(22) Filed: Nov. 26, 2025

Related U.S. Application Data
(63) Continuation of application No. PCT/CN2023/097662, filed on May 31, 2023.

(51) Int. Cl. H03M 13/11

(52) U.S. Cl. CPC H03M 13/116

(57) ABSTRACT

Low density parity check (LDPC) codes for wireless communications are constructed to adapt to channel conditions. A method of encoding input bits by an LDPC code to obtain encoded bits is provided. A method of decoding the encoded bits is also provided. The LDPC code has a parity check matrix obtained by lifting a protograph matrix according to a lifting matrix, in which the lifting matrix is based on a polar kernel.

### CROSS-REFERENCE TO RELATED APPLICATION

The present application is a continuation of International Application No. PCT/CN2023/097662, filed on May 31, 2023, the disclosure of which is hereby incorporated by reference in its entirety.

### TECHNICAL FIELD

This application relates to a low density parity check coding and, in particular, to a protograph-based low density parity check coding.

### BACKGROUND

In wireless communications, the conditions of a channel may change constantly due to fading effects at both fast and slow scales. Modulation and coding scheme (MCS) adaptation is a powerful method to mitigate variations in channel state, in which the MCS scheme (e.g., modulation order, code length and/or coding rate) may be changed in real time. To enable MCS adaptation, the channel coding scheme must allow for flexibly changing the code length and code rate in a fine-grained way, and at the same time achieve good error correction performance in all possible configurations. This fine-grained flexibility of channel codes remains a challenging problem. Typically, probabilistic codes such as low density parity check (LDPC) codes, which are more like random codes, are naturally better suited for this purpose. Algebraic codes, such as Reed-Muller (RM) codes and Bose-Chaudhuri-Hocquenghem (BCH) codes, are not as flexible as probabilistic codes because their inherent coding structures may be compromised when code length or rate changes. Polar codes exhibit features from both probabilistic codes and algebraic codes. As a result, polar codes exhibit a level of flexibility in between probabilistic codes and algebraic codes. Currently, several rate matching schemes, including puncturing and shortening, are available to design rate-compatible polar codes, such as the polar codes used in 5th Generation (5G) New Radio (NR). However, the degree of flexibility provided by these codes may be insufficient to support more advanced features such as fine-grained incremental-redundancy hybrid automatic repeat request (IR-HARQ).

### SUMMARY

According to aspects of the present disclosure, input bits may be encoded with an LDPC code that has a parity check matrix obtained by lifting a protograph matrix based on a polar kernel. Using an LDPC code that was obtained by lifting a protograph matrix based on a polar kernel can speed up decoding convergence because the structure of the resulting LDPC code encourages directional mutual information flow during decoding, thereby improving the convergence speed and decoding efficiency of the LDPC code. In addition, polar kernels of different sizes can be easily constructed, resulting in a less restricted coding structure which can be more easily adapted to account for changes in the state of the channel.

In an aspect, a method is provided. The method involves encoding input bits by an LDPC code to obtain encoded bits and outputting the encoded bits. The LDPC code has a parity check matrix obtained by lifting a protograph matrix according to a lifting matrix. The lifting matrix is based on a polar kernel.

The parity check matrix may have been obtained by replacing a first entry in the protograph matrix with the lifting matrix and replacing a second entry in the protograph matrix with a first circulant matrix comprising a permutation of a first identity matrix.

The parity check matrix may have been obtained by lifting the protograph matrix according to a lifting indicator. The lifting indicator may have indicated that the first entry was to be replaced by the lifting matrix, and the second entry was to be replaced by first circulant matrix.

Lifting the protograph matrix according to the lifting matrix may have involved replacing a first entry in the protograph matrix having a first value with the lifting matrix and replacing a second entry in the protograph matrix having a second value with a first zero matrix having same dimensions as the lifting matrix. Alternatively, lifting the protograph matrix according to the lifting matrix may have involved replacing a first entry in the lifting matrix having a first value with the protograph matrix and replacing a second entry in the lifting matrix having a second value with a second zero matrix that has same dimensions as the protograph matrix.

The lifting matrix may include a circular shift of the polar kernel.

The parity check matrix may have obtained by lifting the protograph matrix according to one of the lifting matrix and a second circulant matrix to obtain an intermediate matrix and lifting the intermediate matrix according to the other of the lifting matrix and the second circulant matrix. The second circulant matrix may comprise a permutation of a second identity matrix.

The polar kernel may include an Arikan kernel. The polar kernel may include a full rank submatrix of an Arikan kernel.

Outputting the encoded bits may involve transmitting the encoded bits from a first communication device to a second communication device in a wireless communication network.

An apparatus configured to perform the above-mentioned method is also provided. The apparatus may include a processor and a memory (e.g., a non-transitory processor-readable medium). The memory may store instructions (e.g., processor-readable instructions) which, when executed by a processor of an apparatus, cause the apparatus to perform the method above. In another aspect, the memory may be provided (e.g., separate to the apparatus). In another aspect, an apparatus comprising a processor is provided. The apparatus is configured to cause the apparatus to perform the above-mentioned method.

In another aspect, a method is provided. The method involves receiving encoded bits encoded by an LDPC code and decoding the encoded bits to obtain decoded input bits. The LDPC code has a parity check matrix obtained by lifting a protograph matrix according to a lifting matrix, in which the lifting matrix is based on a polar kernel.

Decoding the encoded bits may involve decoding the encoded bits using a belief propagation procedure.

The parity check matrix may have been obtained by replacing a first entry in the protograph matrix with the lifting matrix and replacing a second entry in the protograph matrix with a first circulant matrix comprising a permutation of a first identity matrix.

The parity check matrix may have been obtained by lifting the protograph matrix according to a lifting indicator. The lifting indicator may have indicated that the first entry was to be replaced by the lifting matrix, and the second entry was to be replaced by first circulant matrix.

Lifting the protograph matrix according to the lifting matrix may have involved replacing a first entry in the protograph matrix having a first value with the lifting matrix and replacing a second entry in the protograph matrix having a second value with a first zero matrix having same dimensions as the lifting matrix. Alternatively, lifting the protograph matrix according to the lifting matrix may have involved replacing a first entry in the lifting matrix having a first value with the protograph matrix and replacing a second entry in the lifting matrix having a second value with a second zero matrix that has same dimensions as the protograph matrix.

The lifting matrix may involve a circular shift of the polar kernel.

The parity check matrix may have been obtained by lifting the protograph matrix according to one of the lifting matrix and a second circulant matrix to obtain an intermediate matrix, and lifting the intermediate matrix with the other of the lifting matrix and the second circulant matrix. The second circulant matrix may include a permutation of a second identity matrix.

The polar kernel may include an Arikan kernel. The polar kernel may include a full rank submatrix of an Arikan kernel.

Receiving the encoded bits may involve receiving the encoded bits from a first communication device by a second communication device in a wireless communication network.

An apparatus configured to perform the above-mentioned method is also provided. The apparatus may include a processor and a memory (e.g., a non-transitory processor-readable medium). The memory may store instructions (e.g., processor-readable instructions) which, when executed by a processor of an apparatus, cause the apparatus to perform the method above. In another aspect, the memory may be provided (e.g., separate to the apparatus). In another aspect, an apparatus comprising a processor is provided. The apparatus is configured to cause the apparatus to perform the above-mentioned method.

In another aspect, an apparatus is provided. The apparatus includes an encoder for encoding input bits by an LDPC code to obtain encoded bits. The LDPC code has a parity check matrix obtained by lifting a protograph matrix according to a lifting matrix. The lifting matrix is based on a polar kernel. The apparatus also includes an interface, coupled to the encoder, for outputting the encoded bits.

The parity check matrix may have been obtained by replacing a first entry in the protograph matrix with the lifting matrix and replacing a second entry in the protograph matrix with a first circulant matrix comprising a permutation of a first identity matrix.

The parity check matrix may have been obtained by lifting the protograph matrix according to a lifting indicator. The lifting indicator may have indicated that the first entry was to be replaced by the lifting matrix, and the second entry was to be replaced by first circulant matrix.

Lifting the protograph matrix according to the lifting matrix may have involved replacing a first entry in the protograph matrix having a first value with the lifting matrix and replacing a second entry in the protograph matrix having a second value with a first zero matrix having same dimensions as the lifting matrix. Alternatively, lifting the protograph matrix according to the lifting matrix may have involved replacing a first entry in the lifting matrix having a first value with the protograph matrix and replacing a second entry in the lifting matrix having a second value with a second zero matrix that has same dimensions as the protograph matrix.

The lifting matrix may include a circular shift of the polar kernel.

The parity check matrix may have been obtained by lifting the protograph matrix according to one of the lifting matrix and a second circulant matrix to obtain an intermediate matrix, and lifting the intermediate matrix according to the other of the lifting matrix and the second circulant matrix. The second circulant matrix may include a permutation of a second identity matrix.

The polar kernel may include an Arikan kernel. The polar kernel may include a full rank submatrix of an Arikan kernel.

The interface may be for outputting the encoded bits by transmitting the encoded bits from a first communication device to a second communication device in a wireless communication network.

In another aspect, an apparatus is provided. The apparatus includes an interface for receiving encoded bits encoded by an LDPC code. The LDPC code has a parity check matrix obtained by lifting a protograph matrix according to a lifting matrix. The lifting matrix is based on a polar kernel. The apparatus also includes a decoder, coupled to the interface, for decoding the encoded bits to obtain decoded input bits.

The decoder may be for decoding the encoded bits by decoding the encoded bits using a belief propagation procedure.

The parity check matrix may have been obtained by replacing a first entry in the protograph matrix with the lifting matrix and replacing a second entry in the protograph matrix with a first circulant matrix comprising a permutation of a first identity matrix.

The parity check matrix may have been obtained by lifting the protograph matrix according to a lifting indicator. The lifting indicator may have indicated that the first entry was to be replaced by the lifting matrix, and the second entry was to be replaced by first circulant matrix.

Lifting the protograph matrix according to the lifting matrix may have involved replacing a first entry in the protograph matrix having a first value with the lifting matrix and replacing a second entry in the protograph matrix having a second value with a first zero matrix having same dimensions as the lifting matrix. Alternatively, lifting the protograph matrix according to the lifting matrix may have involved replacing a first entry in the lifting matrix having a first value with the protograph matrix and replacing a second entry in the lifting matrix having a second value with a second zero matrix that has same dimensions as the protograph matrix.

The lifting matrix may include a circular shift of the polar kernel. The parity check matrix may have been obtained by lifting the protograph matrix according to one of the lifting matrix and a second circulant matrix to obtain an intermediate matrix, and lifting the intermediate matrix with the other of the lifting matrix and the second circulant matrix. The second circulant matrix comprising a permutation of a second identity matrix.

The polar kernel may include an Arikan kernel. The polar kernel may include a full rank submatrix of an Arikan kernel.

The interface may be for receiving the encoded bits by receiving the encoded bits from a first communication device by a second communication device in a wireless communication network.

### BRIEF DESCRIPTION OF THE DRAWINGS

For a more complete understanding of the present embodiments, and the advantages thereof, reference is now made, by way of example, to the following descriptions taken in conjunction with the accompanying drawings, in which:

FIG. 1 is a schematic diagram of a communication system in which embodiments of the disclosure may occur.

FIG. 2 is another schematic diagram of a communication system in which embodiments of the disclosure may occur.

FIG. 3 is a block diagram illustrating units or modules in a device in which embodiments of the disclosure may occur.

FIG. 4 is a block diagram illustrating units or modules in a device in which embodiments of the disclosure may occur.

FIGS. 5 and 6 show examples of parity check matrices of LDPC codes obtained by lifting a protograph matrix using circulant matrices.

FIGS. 7 and 8 show examples of parity check matrices of LDPC codes obtained by lifting the protograph matrix using polar kernels according to embodiments of the disclosure.

FIGS. 9 and 10 show examples of parity check matrices of LDPC codes obtained by lifting the protograph matrix according to lifting matrices that are based on polar kernels according to embodiments of the disclosure.

FIG. 11 shows an example of a parity check matrix of an LDPC code obtained by lifting the protograph matrix according to a two-stage lifting procedure according to embodiments of the disclosure.

FIG. 12 shows an example of a parity check matrix of an LDPC code obtained by lifting the protograph matrix according to a hybrid lifting procedure according to embodiments of the disclosure.

FIG. 13 shows an example of a parity check matrix of an LDPC code obtained by lifting the protograph matrix according to a two-stage hybrid lifting procedure according to embodiments of the disclosure.

FIGS. 14-15 show flowcharts of methods according to embodiments of the disclosure.

### DETAILED DESCRIPTION

The operation of the current example embodiments and the structure thereof are discussed in detail below. It should be appreciated, however, that the present disclosure provides many applicable inventive concepts that can be embodied in any of a wide variety of specific contexts. The specific embodiments discussed are merely illustrative of specific structures of the disclosure and ways to operate the disclosure, and do not limit the scope of the present disclosure.

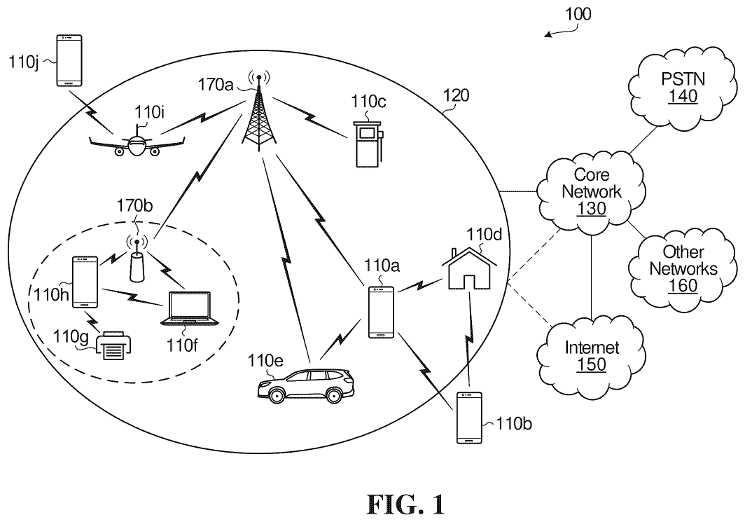

Referring to FIG. 1, as an illustrative example without limitation, a simplified schematic illustration of a communication system is provided. The communication system 100 comprises a radio access network 120. The radio access network 120 may be a next generation (e.g., sixth generation (6G) or later) radio access network, or a legacy (e.g., 5G, 4G, 3G or 2G) radio access network. One or more communication electronic device (ED) 110a-110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also, the communication system 100 comprises a public switched telephone network (PSTN) 140, the internet 150, and other networks 160.

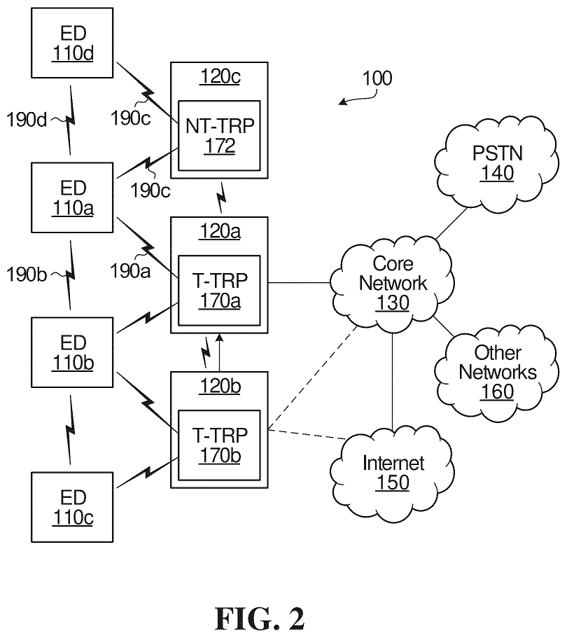

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of the terrestrial communication system and the non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown, the communication system 100 includes electronic devices (ED) 110a-110d (generically referred to as ED 110), radio access networks (RANs) 120a-120b, non-terrestrial communication network 120c, a core network 130, a public switched telephone network (PSTN) 140, the internet 150, and other networks 160. The RANs 120a-120b include respective base stations (BSs) 170a-170b, which may be generically referred to as terrestrial transmit and receive points (T-TRPs) 170a-170b. The non-terrestrial communication network 120c includes an access node 120c, which may be generically referred to as a non-terrestrial transmit and receive point (NT-TRP) 172.

Any ED 110 may be alternatively or additionally configured to interface, access, or communicate with any other T-TRP 170a-170b and NT-TRP 172, the internet 150, the core network 130, the PSTN 140, the other networks 160, or any combination of the preceding. In some examples, ED 110a may communicate an uplink and/or downlink transmission over an interface 190a with T-TRP 170a. In some examples, the EDs 110a, 110b and 110d may also communicate directly with one another via one or more sidelink air interfaces 190b. In some examples, ED 110d may communicate an uplink and/or downlink transmission over an interface 190c with NT-TRP 172.

The air interfaces 190a and 190b may use similar communication technology, such as any suitable radio access technology. For example, the communication system 100 may implement one or more channel access methods, such as code division multiple access (CDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs and one or multiple NT-TRPs for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANS 120a and 120b or EDs 110a 110b, and 110c or both, and (ii) other networks (such as the PSTN 140, the internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

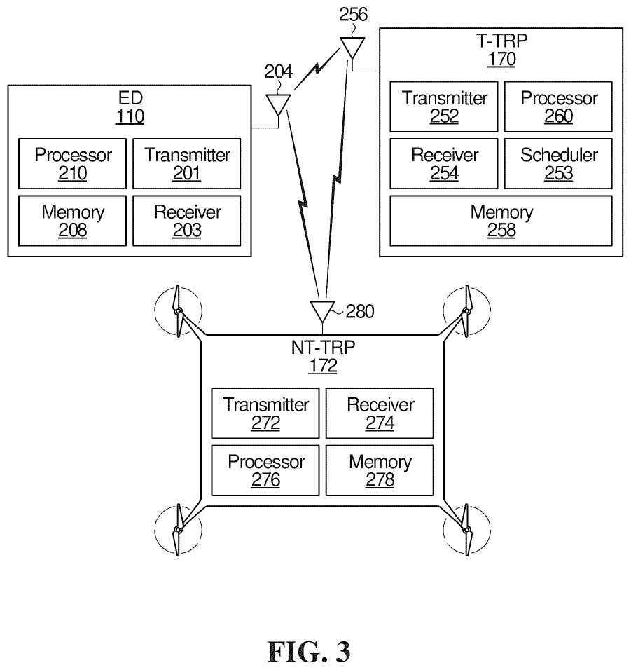

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), internet of things (IOT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g., communication module, modem, or chip) in the foregoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated. One, some, or all of the antennas may alternatively be panels. The transmitter 201 and the receiver 203 may be integrated, e.g., as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by the processing unit(s) 210. Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the internet 150 in FIG. 1). The input/output devices permit interaction with a user or other devices in the network. Each input/output device includes any suitable structure for providing information to or receiving information from a user, such as a speaker, microphone, keypad, keyboard, display, or touch screen, including network interface communications.

The ED 110 further includes a processor 210 for performing operations including those related to preparing a transmission for uplink transmission to the NT-TRP 172 and/or T-TRP 170, those related to processing downlink transmissions received from the NT-TRP 172 and/or T-TRP 170, and those related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by NT-TRP 172 and/or T-TRP 170. In some embodiments, the processor 276 implements the transmit beamforming and/or receive beamforming based on the indication of beam direction, e.g., beam angle information (BAI), received from T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or T-TRP 170.

Although not illustrated, the processor 210 may form part of the transmitter 201 and/or receiver 203. Although not illustrated, the memory 208 may form part of the processor 210.

The processor 210, and the processing components of the transmitter 201 and receiver 203 may each be implemented by the same or different one or more processors that are configured to execute instructions stored in a memory (e.g., in memory 208). Alternatively, some or all of the processor 210, and the processing components of the transmitter 201 and receiver 203 may be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP)), a site controller, an access point (AP), or a wireless router, a relay station, a terrestrial node, a terrestrial network device, or a terrestrial base station, base band unit (BBU), remote radio unit (RRU), active antenna unit (AAU), remote radio head (RRH), central unit (CU), distributed unit (DU), positioning node, among other possibilities. The T-TRP 170 may be macro BSs, pico BSs, relay node, donor node, or the like, or combinations thereof. The T-TRP 170 may refer to the forging devices or apparatus (e.g., communication module, modem, or chip) in the foregoing devices.

In some embodiments, the parts of the T-TRP 170 may be distributed. For example, some of the modules of the T-TRP 170 may be located remote from the equipment housing the antennas of the T-TRP 170, and may be coupled to the equipment housing the antennas over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment housing the antennas of the T-TRP 170. The modules may also be coupled to other T-TRPs. In some embodiments, the T-TRP 170 may actually be a plurality of T-TRPs that are operating together to serve the ED 110, e.g., through coordinated multipoint transmissions.

The T-TRP 170 includes at least one transmitter 252 and at least one receiver 254 coupled to one or more antennas 256. Only one antenna 256 is illustrated. One, some, or all of the antennas may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to NT-TRP 172, and processing a transmission received over backhaul from the NT-TRP 172. Processing operations related to preparing a transmission for downlink or backhaul transmission may include operations such as encoding, modulating, precoding (e.g., MIMO precoding), transmit beamforming, and generating symbols for transmission. Processing operations related to processing received transmissions in the uplink or over backhaul may include operations such as receive beamforming, and demodulating and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates the indication of beam direction, e.g., BAI, which may be scheduled for transmission by scheduler 253. The processor 260 performs other network-side processing operations described herein, such as determining the location of the ED 110, determining where to deploy NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling”, as used herein, may alternatively be called control signaling. Dynamic signaling may be transmitted in a control channel, e.g., a physical downlink control channel (PDCCH), and static or semi-static higher layer signaling may be included in a packet transmitted in a data channel, e.g., in a physical downlink shared channel (PDSCH).

A scheduler 253 may be coupled to the processor 260. The scheduler 253 may be included within or operated separately from the T-TRP 170, which may schedule uplink, downlink, and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or receiver 254. Also, although not illustrated, the processor 260 may implement the scheduler 253. Although not illustrated, the memory 258 may form part of the processor 260.

The processor 260, the scheduler 253, and the processing components of the transmitter 252 and receiver 254 may each be implemented by the same or different one or more processors that are configured to execute instructions stored in a memory, e.g., in memory 258. Alternatively, some or all of the processor 260, the scheduler 253, and the processing components of the transmitter 252 and receiver 254 may be implemented using dedicated circuitry, such as a FPGA, a GPU, or an ASIC.

Although the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g., MIMO precoding), transmit beamforming, and generating symbols for transmission. Processing operations related to processing received transmissions in the uplink or over backhaul may include operations such as receive beamforming, and demodulating and decoding received symbols. In some embodiments, the processor 276 implements the transmit beamforming and/or receive beamforming based on beam direction information (e.g., BAI) received from T-TRP 170. In some embodiments, the processor 276 may generate signaling, e.g., to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or receiver 274. Although not illustrated, the memory 278 may form part of the processor 276.

The processor 276 and the processing components of the transmitter 272 and receiver 274 may each be implemented by the same or different one or more processors that are configured to execute instructions stored in a memory, e.g., in memory 278. Alternatively, some or all of the processor 276 and the processing components of the transmitter 272 and receiver 274 may be implemented using dedicated circuitry, such as a programmed FPGA, a GPU, or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

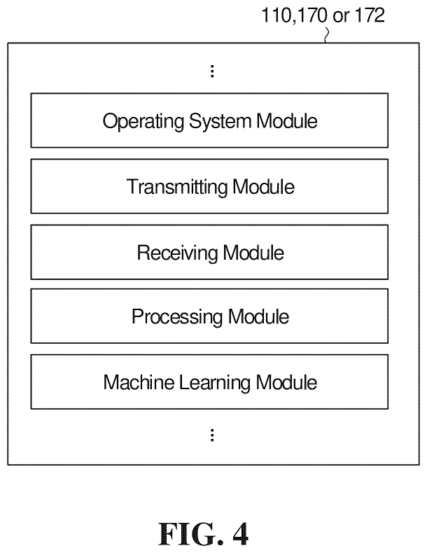

One or more steps of the embodiment methods provided herein may be performed by corresponding units or modules, according to FIG. 4. FIG. 4 illustrates units or modules in a device, such as in ED 110, in T-TRP 170, or in NT-TRP 172. For example, a signal may be transmitted by a transmitting unit or a transmitting module. For example, a signal may be transmitted by a transmitting unit or a transmitting module. A signal may be received by a receiving unit or a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU, or an ASIC. It will be appreciated that where the modules are implemented using software for execution by a processor for example, they may be retrieved by a processor, in whole or part as needed, individually or together for processing, in single or multiple instances, and that the modules themselves may include instructions for further deployment and instantiation.

Additional details regarding the EDs 110, T-TRP 170, and NT-TRP 172 are known to those of skill in the art. As such, these details are omitted here.

### Low Density Parity Check Codes

A low density parity check (LDPC) code may be defined by its parity check matrix, H. Each row in the parity check matrix H represents a parity check function, in which the position of a 1 in a respective row of the matrix corresponds to the code bits that engage in the parity check function. For example, a row [1,0,0,1,0,1] in a parity check matrix H may indicate that the exclusive OR (XOR) of the 1st, 4th, and 6th code bits has to be 0 to pass the parity-check function. A code word c of the LDPC code may be generated such that it passes all the parity checks defined by the rows of H. That is, the code word and the parity check matrix H satisfy the following relation:

$$H \cdot c = 0$$

The parity-check matrix of a LDPC code has low density. That is, it has more 0s than 1s. Fifth Generation (5G) networks have adopted a protograph-based quasi-cyclic LDPC code design, in which the parity-check matrix of the LDPC code is generated by replacing each 1 in a pre-defined protograph matrix with one or more circulant matrices. The process is called lifting the protograph matrix and results in a lifted protograph matrix. The lifted protograph matrix is used as the parity check matrix for the LDPC code. An LDPC code obtained by lifting a protograph matrix may be referred to as a protograph-based LDPC code.

A protograph matrix may be a base matrix from which a parity check matrix is constructed. When the protograph matrix is lifted, each entry (e.g., each element) in the protograph matrix is replaced by a respective matrix, which effectively expands the protograph matrix. The value of an entry in the protograph matrix indicates whether, when the protograph matrix is lifted, the entry is to be replaced by a zero matrix or a circulant matrix. Typically, the entries of a protograph matrix have a value of either 0 or 1, with a 0 indicating that the respective entry is to be replaced by a zero matrix and a 1 indicating that the respective entry is to be replaced by a circulant matrix. In other examples described below, a protograph matrix such as a lifting indicator may further include other values in addition to 0 and 1.

Each circulant matrix is a permutation of an identity matrix, in which each row of a particular circulant matrix is composed of the same entries and is rotated one entry to the right relative to the preceding row. This may also be described as each circulant matrix being a circular shift of an identity matrix. The circular shift may be column-wise or row-wise. The one or more circulant matrices may thus alternatively be referred to as one or more circular shifted identity matrices. A circulant matrix may alternatively be referred to as a circulant.

Each of the one or more circulant matrices used to lift a protograph matrix is a square matrix of the same size (e.g., may be a 2×2 matrix, a 3×3 matrix or a 4×4 matrix etc.). Each of the one or more circulant matrices may be circularly shifted by the same value or different values. The number of rows or columns by which the identity matrix is shifted to result in a particular circulant matrix may be referred to as the shifting value of the circulant matrix. Thus, an identity matrix may be described as a circulant matrix with a shifting value of 0.

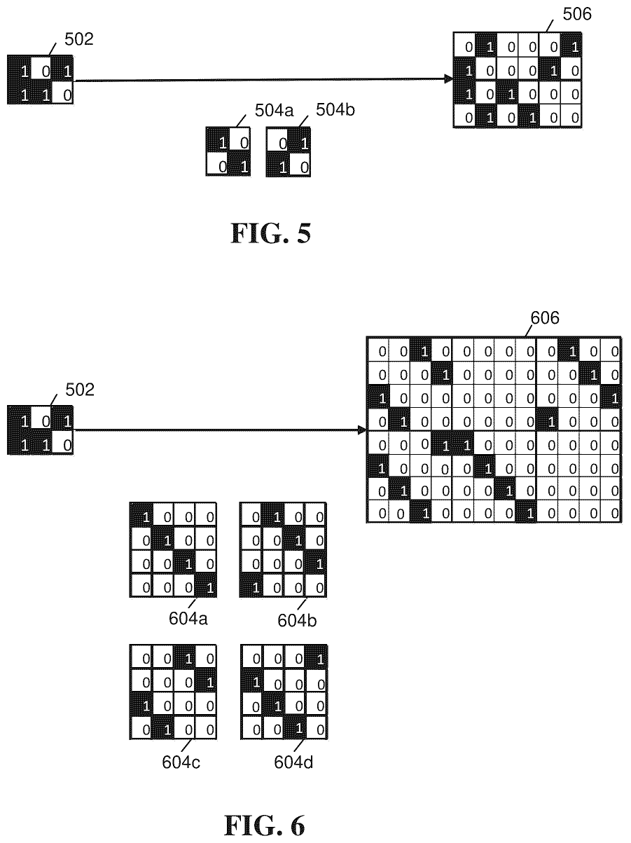

FIG. 5 shows an example of a parity check matrix 506 of an LDPC code obtained by lifting a protograph matrix 502 using a first circulant matrix 504a and a second circulant matrix 504b. In this example, the protograph matrix 502 comprises a 2×6 matrix, in which each entry of the matrix comprises either a 0 or a 1. The first circulant matrix 504 comprises a 2×2 identity matrix. That is, the first circulant matrix 504 is a 2×2 identity matrix that has been column-wise circular shifted by 0 columns. The second circulant matrix 504b comprises a 2×2 identity matrix in which each column has been shifted 1 column to the left or right, which are equivalent in this example. To lift the protograph matrix 502, the is in the top row of the protograph matrix 502 are replaced with the first circulant matrix 504a and the is in the bottom row of the protograph matrix 502 are replaced with the second circulant matrix 504b. The 0s, whether they are in the top or bottom row, are replaced with a 2×2 zero or null matrix (e.g., a matrix in which all of the entries are zero). This results in a 4×6 matrix. Thus, lifting a 2×3 protograph matrix with 2×2 circulant matrices results in a 4×6 parity check matrix.

Another example is shown in FIG. 6, in which the same protograph matrix 502 is lifted using a first circulant matrix 604a, a second circulant matrix 604b, a third circulant matrix 604c and a fourth circulant matrix 604d to obtain a parity check matrix 606. The first, second, third and fourth circulant matrices 604a, 604b, 604c, 604d comprise column-wise circular shifts of the 4×4 identity matrix with shifting values 0, 1, 2 and 3 respectively. Lifting the 2×3 protograph matrix 502 with the 4×4 circulant matrices 604 results in an 8×12 parity check matrix.

A comparison of FIGS. 5 and 6 illustrates how lifting the protograph matrix 502 with different circulant matrices can result in different parity check matrices 506, 606. In general, a protograph matrix, such as the protograph matrix 502, may be lifted by replacing each 1 in the protograph matrix with a respective Z×Z matrix generated by shifting the columns of a Z×Z identity matrix by a shifting value in the range 0, 1, . . . , Z−1.

Protograph-based LDPC codes may be used to obtain LDPC codes with variable code length and/or code rate. To achieve a longer code, the protograph matrix may be lifted with a larger circulant matrix (e.g., a circulant matrix with more rows and columns). To achieve a shorter code, the protograph matrix may be lifted with a smaller circulant matrix (e.g., a circulant matrix with fewer rows and columns). To achieve a higher code rate, fewer rows of the protograph matrix may be selected (e.g., which effectively means that a smaller protograph matrix is lifted). To achieve a lower code rate, more rows of the protograph matrix may be selected (e.g., which effectively means that a larger protograph matrix is lifted). Selecting more rows from the protograph matrix for lifting results in a parity check matrix associated with more parity checks, and thus a lower code rate.

As such, it is possible to dynamically adapt protograph-based LDPC codes according to channel conditions. This makes LDPC codes flexible and particularly well suited for wireless communications. However, this LDPC design is still channel independent, which means that it cannot adapt to dynamic channel changes within a packet (e.g., within a code word).

LDPC codes, including protograph-based LDPC codes, are typically decoded using a belief propagation procedure (e.g., process or algorithm), including variants of belief propagation procedures such as min-sum (MS) decoding. A belief propagation procedure may essentially involve passing beliefs (e.g., in the form of log-likelihood ratios or likelihoods) on the edges between variable nodes and check nodes in a factor graph, in which a variable node represents a code bit (e.g., a column in the parity check matrix) and a check node represents a parity check function (e.g., a row in the parity check matrix). Two examples of belief propagation procedures are flooding belief propagation and layered belief propagation. Flooding belief propagation, or flooding min-sum decoding, involves passing all messages simultaneously in particular iterations. Layered belief propagation, or layered min-sum decoding, involves passing the messages on edges connected to a check node at a particular time, and the check nodes taking turns to be processed.

The parity check matrices of existing protograph-based LDPC codes are typically designed to be decoded by flooding or layered belief propagation procedures. However, these belief propagation procedures cannot accurately control the direction of mutual information flow on the factor graph. This means that information gained during decoding may not be effectively used to aid in decoding, reducing decoding efficiency. Typically, the structure of the parity check matrices of protograph-based LDPC codes does not mitigate this. That is, the parity check matrix of typical protograph-based LDPC does not have a clear structure to aid scheduled decoding. These factors limit the design space for existing LDPC codes.

According to aspects of the present disclosure, the parity check matrix of an LDPC code may be obtained by lifting a protograph matrix based on a polar kernel. Lifting a protograph matrix based on a polar kernel may be referred to as polarized lifting. When polar codes are decoded (e.g., using a successive cancellation, SC, based decoder), the decoder can precisely guide the flow of mutual information received from the channel to every information bit (variable node), resulting in more efficient and quicker decoding. Using an LDPC code that was obtained by lifting a protograph matrix based on a polar kernel can speed up decoding convergence because the structure of the resulting LDPC code encourages directional mutual information flow during decoding, thereby improving the convergence speed and decoding efficiency of the LDPC code. In addition, the “polarization” or “unevenness” in a parity-check matrix obtained by lifting a protograph matrix based on a polar kernel allows for more flexible decoding scheduling.

As polar kernels of different sizes can be easily constructed (e.g., through shortening of an Arikan kernel), this provides a less restricted coding structure, which can be better adapted to changes in the state of the channel.

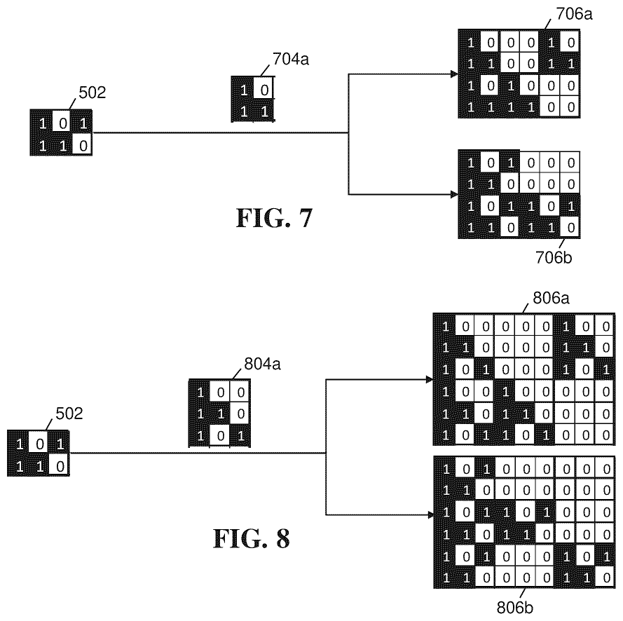

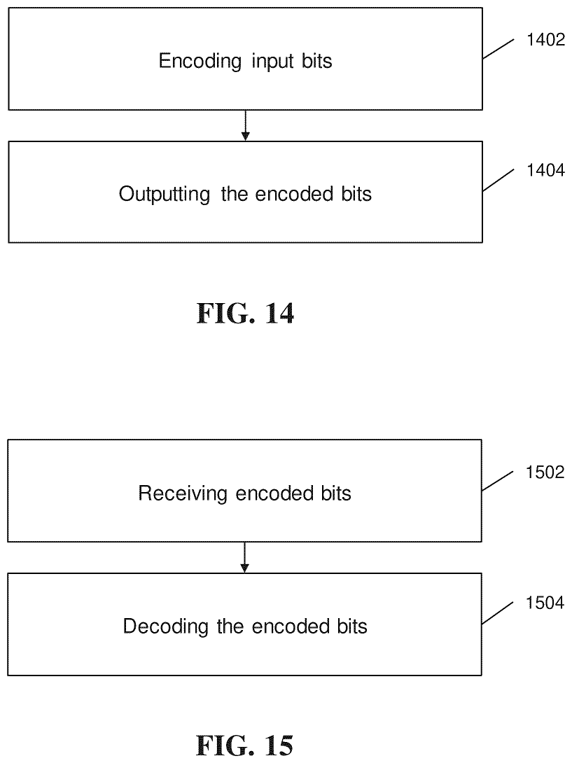

Example embodiments of lifting a protograph matrix based on a polar kernel are described with reference to FIGS. 7-13. Each of these embodiments uses the same protograph matrix 502 for ease of understanding the different examples. However, it will be understood that, in general, any suitable protograph matrix may be used. Moreover, in some examples, the protograph matrix may be a submatrix (e.g., a matrix extracted from) a larger protograph matrix. This is described in more detail below in respect of FIG. 14.

In the context of the present disclosure, a polar kernel may be any generator matrix of a polar code. The generator matrix of a polar code with length N may be denoted G_{N}. For polar codes with a length equal to a power of 2 (e.g., N=2^{x}, in which x is an integer), the generator matrix (e.g., the polar kernel) may be expressed as

$${G}_{N} = {F}_{2}^{{⊗}_{n}} , \qquad ( 1 )$$

in which

$${F}_{2} = [ \begin{matrix}1 & 0 \\ 1 & 1\end{matrix} ] , \qquad ( 2 )$$

is a polarization kernel matrix, n=log₂ N and ⊗ is a Kronecker product. The resulting polar kernel (e.g., a polar kernel defined according to Equation (1)) may be referred to as an Arikan kernel. Arikan kernels are full rank. That is, an Arikan kernel of a polar code with length N has the maximum number of linearly independent columns that are possible for an N×N matrix.

For polar codes with a length that is not equal to a power of 2, the polar kernel may be a submatrix of

$${F}_{2}^{{⊗}_{n}}$$

as defined above, in which the submatrix is a full rank matrix. Thus, a polar kernel may comprise an Arikan kernel or a submatrix of an Arikan kernel. In either case, the polar kernel is full rank.

Obtaining a submatrix of an Arikan kernel may referred to as shortening an Arikan kernel. There are various known approaches for shortening an Arikan kernel to obtain a polar kernel, including bit-reversed shortening and reverse shortening. Further information regarding bit-reversed shortening may be found in R. Wang and R. Liu, “A Novel Puncturing Scheme for Polar Codes,” in IEEE Communications Letters, vol. 18, no. 12, pp. 2081-284 December 2014, doi: 10.1109/LCOMM.2014.2364845. Reverse shortening an Arikan kernel may involve shortening the Arikan kernel from the last row and last column of the kernel e.g., from row and column N, N−1, N−2, etc. In the context of the present disclosure, any suitable method may be used to obtain a full rank submatrix of an Arikan kernel for use as a polar kernel.

By way of example, the 2×2 polar kernel may be expressed as

$${G}_{2} = [ \begin{matrix}1 & 0 \\ 1 & 1\end{matrix} ] . \qquad ( 3 )$$

The 3×3 polar kernel may be expressed as:

$${G}_{3} = [ \begin{matrix}1 & 0 & 0 \\ 1 & 1 & 0 \\ 1 & 0 & 1\end{matrix} ] . \qquad ( 4 )$$

The 4×4 polar kernel may be expressed as:

$${G}_{4} = [ \begin{matrix}1 & 0 & 0 & 0 \\ 1 & 1 & 0 & 0 \\ 1 & 0 & 1 & 0 \\ 1 & 1 & 1 & 1\end{matrix} ] . \qquad ( 5 )$$

As will be apparent from comparing Equations (4) and (5), the 3×3 polar kernel G₃ comprises the first three rows and columns of the 4×4 polar kernel G₄ (e.g., is a submatrix of the 4×4 Arikan kernel).

When the 2×2 polar kernel provided in Equation (3) is expressed as a factor graph, the structure of the polar kernel leads to a degree−1 variable node and a degree−2 variable node. Mutual information will flow from the degree−1 variable node to the degree−2 variable node and then back in the opposite direction. This structure helps to better regulate the mutual information flow in the LDPC factor graph during decoding, and speed up the decoding convergence. This mutual information flow is analogously achieved by the 3×3 and 4×4 polar kernels provided in Equations (4) and (5) above, and any N×N polar kernel.

FIG. 7 shows an example of a first parity check matrix 706a of an LDPC code and a second parity check matrix 706b of the LDPC code, in which both the first and second parity check matrices 706a, 706b are obtained by lifting the protograph matrix 502 according to a polar kernel 704a.

The polar kernel 704a comprises the 2×2 Arikan kernel given above in Equation (3). The first parity check matrix 706a is obtained by replacing each 1 in the protograph matrix 502 with the polar kernel 704a and replacing each 0 in the protograph matrix with a 2×2 zero matrix. The second parity check matrix 706b is obtained by replacing each 1 in the polar kernel 704a with the protograph matrix 502, and replacing each 0 in the polar kernel 704a with a 2×3 zero matrix. The first parity check matrix 706a is a row and column permutation of the second parity check matrix 706b, which means that the first and second parity check matrices 706a, 706b lead to the same LDPC code, and thus the same decoding performance.

FIG. 7 thus illustrates two approaches for lifting a protograph matrix using a polar kernel, which may be generalized to any protograph matrix and polar kernel. In the first approach, each 1 in the protograph matrix is replaced with the polar kernel and each 0 in the protograph matrix is replaced with a zero matrix with the same dimensions as the polar kernel. In the second approach, each 1 in the polar kernel is replaced with the protograph matrix and each 0 in the polar kernel is replaced with a zero matrix with the same dimensions as the protograph matrix. Both approaches result in equivalent parity check matrices of an LDPC code that may be used to encode input bits according to embodiments of the disclosure. This is a particular property of using polar kernels to lift a protograph matrix e.g., lifting is communicative for a polar kernel. Some of the examples described herein may only describe one of these lifting approaches in detail. However, it will be understood that the lifting examples described herein may be implemented using either of these lifting approaches.

Another example implementation of these two approaches for lifting a protograph matrix using a polar kernel is described with reference to FIG. 8. FIG. 8 shows an example of a first parity check matrix 806a of an LDPC code and a second parity check matrix 806b of the LDPC code. The first and second parity check matrices 806a, 806b are obtained by lifting the protograph matrix 502 according to a polar kernel 704a.

The polar kernel 804a comprises the 3×3 polar kernel given above in Equation (4). The first parity check matrix 806a is obtained by replacing each 1 in the protograph matrix 502 with the polar kernel 804a and replacing each 0 in the protograph matrix with a 3×3 zero matrix. The second parity check matrix 806b is obtained by replacing each 1 in the polar kernel 804a with the protograph matrix 502, and replacing each 0 in the polar kernel 804a with a 2×3 zero matrix.

As mentioned above, the 3×3 polar kernel 804a is a shortened polar kernel. That is, the polar kernel 804a is a submatrix of the 4×4 Arikan kernel given in Equation (5). As such, FIG. 8 illustrates examples of lifting a protograph matrix (the protograph matrix 502) with a shortened polar kernel. In general, a protograph matrix may be lifted with any polar kernel (e.g., a shortened polar kernel or an Arikan kernel). The size of the kernel used to lift the protograph matrix can affect the code length. Using shortened polar kernels allows for a larger range of kernel sizes, which allows for fine tuning the code length.

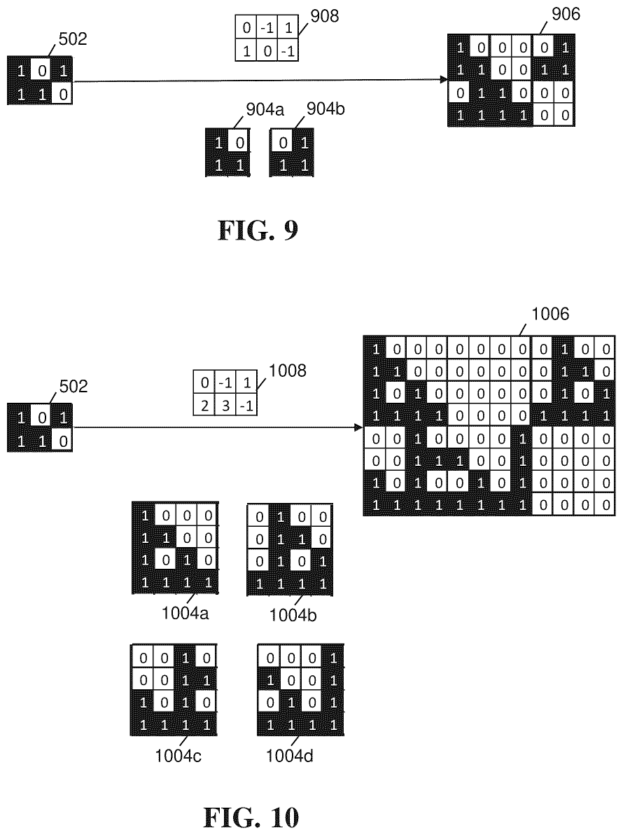

In the examples described above in reference to FIGS. 7 and 8, a parity check matrix is obtained by lifting the protograph matrix 502 using a polar kernel. In general, a parity check matrix may be obtained by lifting a protograph matrix according to (e.g., using) a lifting matrix, in which the lifting matrix is based on a polar kernel. In this context, the lifting matrix being based on the polar kernel might mean that the lifting matrix comprises (e.g., consists of) the polar kernel (e.g., as in the examples described above in respect of FIGS. 7 and 8). Alternatively, the lifting matrix may be obtained by performing a function or operation on the polar kernel. The function or operation may include, for example, a circular shift. The circular shift may be column-wise or row-wise. Examples of lifting a protograph matrix according to a lifting matrix obtained by circularly shifting a polar kernel are described with reference to FIGS. 9 and 10. For ease of description, polar kernels that have not been circularly shifted may be referred to as circular shifted polar kernels with a shifting value of 0.

FIG. 9 shows an example of a parity check matrix 906 of an LDPC code obtained by lifting the protograph matrix 502 according to a first lifting matrix 904a and a second lifting matrix 904b. The first lifting matrix 904a comprises the 2×2 Arikan kernel given above in Equation (3). The first lifting matrix 904a may be described as a (right) column-wise circular shift of the 2×2 Arikan kernel with a shifting value of 0. The second lifting matrix 904b comprises a right column-wise circular shift of the 2×2 Arikan kernel with a shifting value of 1. For a right column-wise shift circular shift of a particular matrix, the shifting value indicates how many columns to the right each entry in the particular matrix is shifted. Thus, the second lifting matrix 904b may be obtained by shifting entries in the first column of the first lifting matrix 904a one column to the right and shifting entries in the second column of the first lifting matrix 904a to the first column.

The parity check matrix 906 is obtained by replacing some of the is in the protograph matrix 502 with the first lifting matrix 904a and the other is in the protograph matrix 502 with the second lifting matrix 904b. The zeros in the protograph matrix 502 are replaced with a 2×2 zero matrix. That is, some entries in the protograph matrix 502 are lifted according to the first lifting matrix 904a and other entries in the protograph matrix 502 are lifted according to the second lifting matrix 904b.

This is illustrated by the lifting indicator 908. Each entry of the lifting indicator 908 indicates which matrix is to replace a respective entry of the protograph matrix 502. The (1,1) entry of the lifting indicator 908 has a value of 0, which indicates that the (1,1) entry of the protograph matrix (which has a value of 1) is to be replaced by the first lifting matrix 904a (e.g., by the 2×2 Arikan kernel with a shifting value of 0). The (1,2) entry of the lifting indicator 908 has a value of −1, which indicates that the (1,2) entry of the protograph matrix 502 (which has a value of 0) is to be replaced by the 2×2 zero matrix. The (1,3) entry of the lifting indicator 908 has a value of 1, which indicates that the (1,3) entry of the protograph matrix 502 (which has a value of 1) is to be replaced by the second lifting matrix 904b (e.g., by the right column-wise circular shifted 2×2 Arikan kernel with shifting value of 1). The (2,1), (2,2) and (2,3) entries of the lifting indicator have values 1, 0 and −1 respectively, indicating that the (2,1), (2,2) and (2,3) entries of the protograph matrix 502 are to be replaced by the second lifting matrix 904b, the first lifting matrix 904a and the 2×2 zero matrix respectively.

FIG. 10 shows another example of a parity check matrix 1006 of an LDPC code obtained by lifting the protograph matrix 502 according to a first lifting matrix 1004a, a second lifting matrix 1004b, a third lifting matrix 1004c and a fourth lifting matrix 1004d. The first lifting matrix 1004a comprises the 4×4 Arikan kernel given above in Equation (5). The second, third and fourth lifting matrices 1004b, 1004c, 1004d comprises right column-wise circular shifts of the 4×4 Arikan kernel with a shifting values of 1, 2 and 3 respectively.

Lifting the protograph matrix 502 in accordance with the first, second, third and fourth lifting matrices 1004a, 1004b, 1004c, 1004d involves replacing the is in the protograph matrix 502 with one of the first, second, third and fourth lifting matrices 1004a, 1004b, 1004c, 1004d. The zeros in the protograph matrix 502 are replaced with a 4×4 zero matrix. The resulting parity check matrix 1006 is an 8×12 matrix.

The lifting indicator 1008 indicates which matrix is to replace each entry of the protograph matrix 502. The (1,1) entry of the lifting indicator 1008 has a value of 0, which indicates that the (1,1) entry of the protograph matrix (which has a value of 1) is to be replaced by the first lifting matrix 1004a. The (1,2) entry of the lifting indicator 1008 has a value of −1, which indicates that the (1,2) entry of the protograph matrix 502 is to be replaced by the 4×4 zero matrix. The (1,3) entry of the lifting indicator 1008 has a value of 1, which indicates that the (1,3) entry of the protograph matrix 502 is to be replaced by the second lifting matrix 1004b. The (2,1), (2,2) and (2,3) entries of the lifting indicator have values 2, 3 and −1 respectively, indicating that the (2,1), (2,2) and (2,3) entries of the protograph matrix 502 are to be replaced by the third lifting matrix 1004c, the fourth lifting matrix 1004d and the 4×4 zero matrix respectively.

FIGS. 9 and 10 illustrate specific examples of lifting a protograph matrix with different circular shifts of a polar kernel (including a polar kernel with a shifting value of 0, or no circular shift). It will be appreciated that this may be generalized to other protograph matrices, other polar kernels and other circular shifts. For example, the circular shifts in the examples in FIGS. 9 and 10 are column-wise circular shifts. In other examples, row-wise circular shifts may be used. That is, rather than shifting the entries of a polar kernel one or more columns to the left or right, entries of the polar kernel may be shifted one or more rows up or down. Accordingly, the shifting value indicates the amount of shift in whatever direction has been established for the shifting scheme.

Using one or more circular shifted polar kernels (e.g., circular shifts with shifting values not equal to 0) to lift the protograph matrix may be particularly advantageous because shifting can reduce the incidence of short cycles in the factor graph, which improves decoding performance.

As described above in the examples shown in FIGS. 9 and 10, a lifting indicator, such as the lifting indicators 908, 1008, may be used to indicate the respective lifting matrix for each entry of the protograph matrix. In the examples shown in FIGS. 9 and 10, the value −1 in the lifting indicator indicates that the corresponding entry in the protograph matrix 502 is to be replacing by a zero matrix and integers with a value N≥0 are used to indicate that the corresponding entries in the protograph matrix 502 is to be replaced by a polar kernel that has been right column-wise circular shifted with a shifting value equal to N. It will be appreciated that this format of the lifting indicator is provided by way of example only. In general, the lifting indicator may comprise a matrix that has the same dimensions as the protograph matrix, in which each entry of the lifting indicator indicates how a particular entry of the protograph matrix is to be lifted (e.g., which matrix is to replace the particular entry). This allows the parity check matrix to be concisely represented, regardless of its size. Since the structure of the protograph matrix (i.e., dimensions, entries, etc.) can be derived from the lifting indictor, the parity check matrix may instead be obtained from the lifting indicator by replacing entries of the lifting indicator with their corresponding null (zero) matrix and lifting matrices. In the sense that the protograph matrix can be represented by the lifting indicator, the lifting indicator may then also be known as another variation of a protograph matrix.

In some examples, the protograph matrix may be lifted in two or more stages. This may be referred to as multi-stage lifting. For example, each entry of the protograph matrix may be lifted (e.g., replaced by a respective matrix) once in a first stage to obtain an intermediate matrix, and each entry of the intermediate matrix may be lifted (e.g., replaced by a respective matrix) to obtain a parity check matrix.

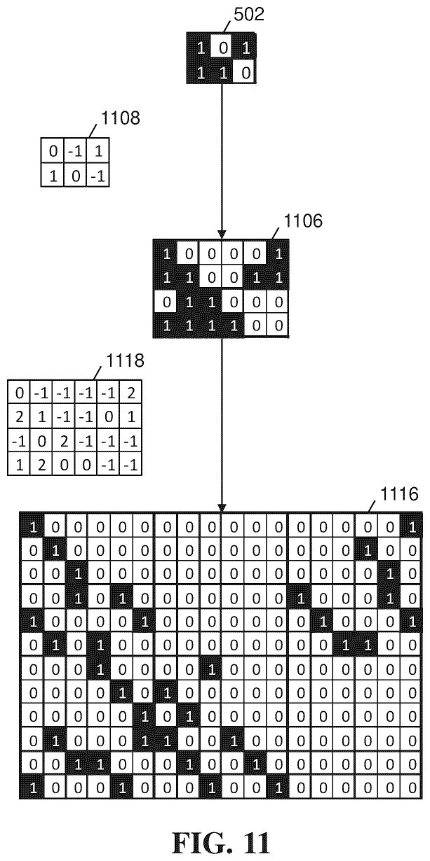

FIG. 11 shows an example of two-stage lifting, in which the protograph matrix 502 is lifted to obtain an intermediate matrix 1106 and the intermediate matrix 1106 is lifted to obtain a parity check matrix 1116.

In the first stage, the protograph matrix 502 is lifted in the same way as described above in respect of FIG. 9. Thus, the intermediate matrix 1106 is the same as the parity check matrix 906 described above in respect of FIG. 9. The lifting indicator 1108 for this first lifting stage is the same as the lifting indicator 908 described above.

In the second stage, the intermediate matrix 1106 is lifted according to first, second and third lifting matrices (not illustrated), in which the first, second and third lifting matrices are right column-wise circular shifts of the 3×3 identity matrix with shifting values of 0, 1 and 2 respectively. Thus, each of the is in the intermediate matrix 1106 are replaced with a circulant matrix e.g., with either the 3×3 identity matrix (e.g., equivalent to a column-wise circular shift with a shifting value of 0) or a column-wise circular shift of the 3×3 identity matrix with a shifting value of 1 or 2. Each 0 in the intermediate matrix 1106 is replaced by a 3×3 zero matrix. The lifting indicator 1118 indicates which matrix replaces each entry of the intermediate matrix 1106. A value of −1 in the lifting indicator 1118 indicates that the corresponding entry in the intermediate matrix 1106 is to be replaced by the 3×3 zero matrix. A value of 0, 1 or 2 in the lifting indicator 1118 indicates that the corresponding entry in the intermediate matrix 1106 is to be replaced by a right column-wise circular shift of the 3×3 identity matrix with a shifting values of 0, 1 or 2 respectively.

FIG. 11 thus shows a two-stage lifting procedure, in which the protograph matrix 502 is lifted using lifting matrices based on a 2×2 Arikan kernel to obtain an intermediate matrix 1106 and the intermediate matrix 1106 is lifted using 3×3 circulant matrices (e.g., circular shifts of a 3×3 identity matrix) kernel to obtain the 12×18 parity check matrix 1116. In this example, the lifting matrices in each stage in the two-stage lifting procedure are based on a different type of matrix: the 2×2 Arikan kernel in the first stage and the 2×2 identity matrix in the second stage. In general, each stage in a multi-stage lifting procedure may be based on the same, or a different, type of matrix. Thus, for example, a protograph matrix may be lifted according to a lifting matrix based on a polar kernel in the first stage and another lifting matrix based on the polar kernel in the second stage. In another example, a protograph matrix may be lifted using a lifting matrix based on an identity matrix in the first stage and according to another lifting matrix based on the polar kernel in the second stage. Lifting procedures which are based on both polar kernels and circulant matrices may be referred to as hybrid lifting. Thus, the example shown in FIG. 11 may be referred to as two-stage hybrid lifting.

For ease of description, two-stage lifting procedures are the only multi-stage lifting procedures described in detail herein. However, it will be appreciated that the principles may be extended to lifting procedures with two or more stages. In some examples of multi-stage lifting procedures, each stage of the lifting procedure may have a respective lifting indicator.

In some examples, each lifting step in a multi-stage lifting procedure, may be indicated by an entry in a lifting sequence (e.g., a lifting list). The lifting sequence may comprise a binary sequence in which a 0 indicates that lifting is to be performed with a lifting matrix based on polar kernel and a 1 indicates that lifting is to be performed with lifting matrix based on an identity matrix (e.g., with a circulant matrix). For example, the two-stage lifting procedure illustrated in FIG. 11 may be represented by the lifting sequence [0,1], in which the first entry (with a value of 0) indicates that the first stage in the two-step lifting procedure is based on a polar kernel and the second entry (with a value of 1) indicates that the second stage in the two-step lifting procedure uses circulant matrices. In another example, a three-stage lifting procedure may be represented by the sequence [1,0,1], indicating that the first stage involves lifting using circulant matrices, the second stage involves lifting based on a polar kernel and the third stage involves lifting using circulant matrices.

A lifting procedure that results in a particular parity check matrix based on a protograph matrix may be associated with a lifting factor, in which the lifting factor indicates the size of the parity check matrix relative to the protograph matrix. For a one-stage lifting procedure, the lifting factor may be equal to the number of rows (or, equivalently, columns) in the lifting matrix (e.g., in the matrix used to lift the protograph matrix). For a multi-stage lifting procedure with N stages, the lifting factor may be given by:

$$Z = {\prod }_{i = 1}^{N} {Z}_{N}$$

in which Zi is the lifting factor for stage i in the lifting procedure. Thus, for example, the lifting procedures shown in FIGS. 7 and 8 have lifting factors Z=2 and Z=3 respectively. The lifting procedures shown in FIGS. 9 and 10 have lifting factors Z=2 and Z=4 respectively. The two-stage lifting procedure shown in FIG. 11 has a lifting factor Z=Zₚ×Z_{c}=2×3=6, in which Zₚ is the lifting factor for the first (polarized) lifting stage and Z_{c} is the lifting factor for the second (circulant matrix) lifting stage.

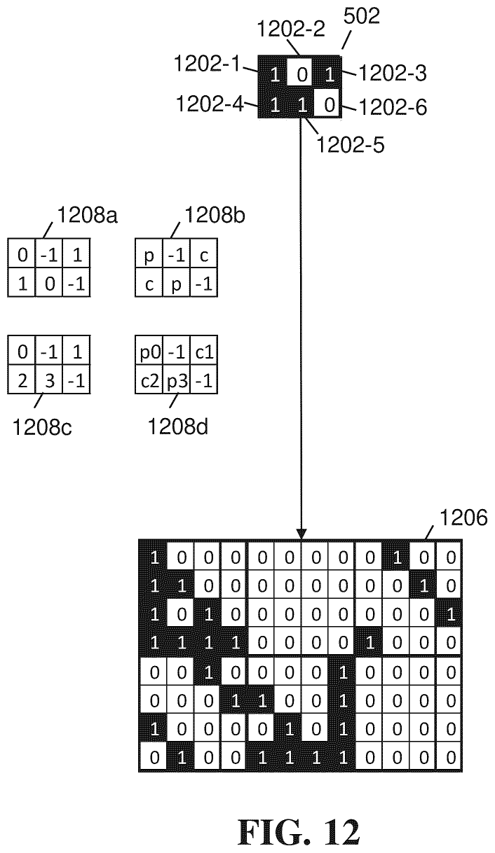

As mentioned above, lifting procedures which are based on both polar kernels and circulant matrices may be referred to as hybrid lifting. Multi-stage lifting in which circulant matrix-based lifting is used for one or more stages and polarized lifting is used for one or more other stages is one example of hybrid lifting. Another example of hybrid lifting involves using circulant matrix-based lifting and polarized lifting in the same step. An example of this is described with reference to FIG. 12.

FIG. 12 shows an example of a parity check matrix 1206 of an LDPC code obtained by lifting some entries of the protograph matrix 502 using polarized lifting and other entries of the protograph matrix 502 using circulant matrix-based lifting.

The protograph matrix 502 has six entries: a first entry 1202-1, a second entry 1202-2, a third entry 1202-3, a fourth entry 1202-4, a fifth entry 1202-5 and a sixth entry 1202-6.

The first entry 1202-1 in the protograph matrix 502 is in the first row and column of the protograph matrix 502. In the lifting procedure, the first entry 1202-1 is replaced by the 4×4 Arikan kernel. The second entry 1202-2 in the protograph matrix 502 is in the first row and second column of the protograph matrix 502, and is replaced by a 4×4 zero matrix in the lifting procedure. The third entry 1202-3 in the protograph matrix 502 is in the first row and third column of the protograph matrix 502, and is replaced by a 4×4 circulant matrix with a shifting value of 1 (e.g., by a 4×4 identity matrix that has been circularly shifted by one column to the right).

The fourth entry 1202-4 in the protograph matrix 502 is in the second row and first column of the protograph matrix 502, and is replaced by a 4×4 circulant matrix with a shifting value of 2 (e.g., by a 4×4 identity matrix that has been circularly shifted by two columns to the right). The fifth entry 1202-5 in the protograph matrix 502 is in the second row and second column of the protograph matrix 502, and is replaced by a 4×4 Arikan kernel with a shifting value of 3 (e.g., by a 4×4 Arikan kernel that has been circularly shifted by three columns to the right). The sixth entry 1202-6 in the protograph matrix 502 is in the second row and third column of the protograph matrix 502, and is replaced by a 4×4 zero matrix in the lifting procedure.

Thus, in the example shown in FIG. 12, among the four non-zero entries in the protograph matrix 502, two entries are replaced by lifting matrices that are based on polar kernels and two entries are replaced by circulant matrices. This may be described as simultaneous hybrid lifting, or simultaneously lifting a protograph matrix based on a (4×4) polar kernel and a (4×4) identity matrix.

FIG. 12 shows four examples of different lifting indicators 1208a, 1208b, 1208c and 1208d that may be used in respect of the lifting procedure shown in FIG. 12. Each of the lifting indicators 1208a, 1208b, 1208c, 1208d has the same dimensions as the protograph matrix 502.

The first and second lifting indicators 1208a, 1208b show two different ways of indicating which entries in the protograph matrix 502 are to be replaced by a circulant matrix, which entries are to be replaced by lifting matrix that is based a polar kernel (e.g., the polar kernel or a circular shift of a polar kernel) and which entries are to be replaced by a zero matrix.

In the first lifting indicator 1208a, a value of −1 indicates that the corresponding entry in the protograph matrix 502 is to be replaced by a zero matrix, a value of 0 indicates that the corresponding entry in the protograph matrix 502 is to be replaced by a lifting matrix that is based on polar kernel, a value of 1 indicates that the corresponding entry in the protograph matrix 502 is to be replaced by a circulant matrix.

In the second lifting indicator 1208a, a value of −1 indicates that the corresponding entry in the protograph matrix 502 is to be replaced by a zero matrix, a value of “p” indicates that the corresponding entry in the protograph matrix 502 is to be replaced by a lifting matrix that is based on polar kernel, a value of “c” indicates that the corresponding entry in the protograph matrix 502 is to be replaced by a circulant matrix.

The third lifting indicator 1208c indicates, for entries to be replaced by a circulant matrix or a polar kernel, the shifting value of the respective circulant matrix or polar kernel. The third lifting indicator 1208c may be referred to as a circular permutation matrix, or a circular permutation indicator. Thus, for example, a value of 2 in the third lifting indicator 1208c indicates that the corresponding entry in the protograph matrix 502 is to be replaced by a polar kernel or identity matrix that has been circularly shifted with a shifting value of 2. For entries that are to be replaced by a zero matrix, the corresponding entry of third lifting indicator 1208c is equal to −1.

The fourth lifting indicator 1208d combines the second and third lifting indicators. The fourth lifting indicator 1208d may be referred to as a joint indicator, or a joint indicator and circular permutation matrix. For each entry of the protograph matrix 502 that is to be replaced by a zero matrix, the fourth lifting indicator 1208d has a value of −1. For each entry of the protograph matrix 502 that is to be replaced by a lifting matrix that is based on a polar kernel, the corresponding entry of fourth lifting indicator 1208d includes the letter “p” and the shifting value of the polar kernel. For example, the entry “p3” in the fourth lifting indicator 1208d indicates that the corresponding entry in the protograph matrix is to be replaced by a polar kernel that has been right column-wise circularly shifted with a shifting value of 3. For each entry of the protograph matrix 502 that is to be replaced by a circulant matrix, the corresponding entry of fourth lifting indicator 1208d includes the letter “c” and the shifting value of the circulant matrix. For example, the entry “c2” in the fourth lifting indicator 1208d indicates that the corresponding entry in the protograph matrix is to be replaced by a circulant matrix with a shifting value of 3 (e.g., by an identity matrix that has been right column-wise circularly shifted by 3 columns).

Using both one of the first and second lifting indicators 1208a, 1208b and the third lifting indicator 1208c, both the lifting type and shifting value for each entry of the protograph matrix 502 may be indicated. Alternatively, this information may be jointly indicated in the fourth lifting indicator 1208d.

Although the lifting indicators 1208a, 1208b, 1208c, 1208d are specific to the lifting procedure shown in FIG. 12, it will be appreciated that the indicators may be generalized to other protograph matrices and/or other lifting procedures. In general, a lifting indicator for a hybrid lifting procedure (e.g., a simultaneous hybrid lifting procedure) may indicate whether each non-zero entry in a protograph matrix is to be lifted by lifting matrix that is based on a polar kernel or a circulant matrix. For example, a 0 may indicate that an entry is to be lifted by lifting matrix that is based on a polar kernel, and 1 may indicate that an entry is to be lifted by a circulant matrix (e.g., as in the first lifting indicator 1208a). As another example, a p may indicate that an entry is to be lifted by a lifting matrix that is based on a polar kernel, and c may indicate that an entry is to be lifted by a circulant matrix (e.g., as in the second lifting indicator 1208b). A lifting indicator may, additionally or alternatively, indicate the shifting values of the lifting matrices (e.g., of the polar kernel and/or the circulant matrix).

FIG. 12 shows just one example of simultaneous hybrid lifting. In general, simultaneous hybrid lifting may involve performing polarized lifting of some of non-zero entries in a protograph matrix and, at the same time, performing circulant matrix-based lifting of the other non-zero entries in the protograph matrix. The lifting factor of a simultaneous hybrid lifting procedure may be given by Z=Zₚ=Z_{c}, in which Zₚ is the lifting factor for polarized lifting and Z, is the lifting factor for circulant matrix-based lifting. Thus, the lifting factor for the lifting procedure shown in FIG. 12 may be Z=4.

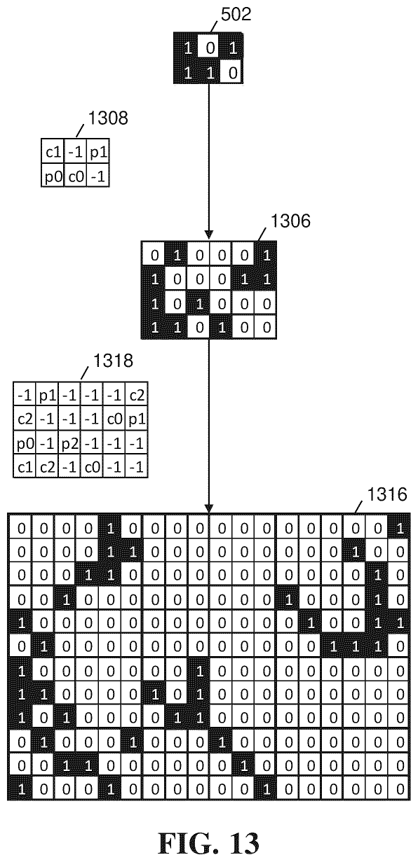

Simultaneous hybrid lifting may be the sole stage in a lifting procedure. Alternatively, simultaneous hybrid lifting may be used in one or more stages of a multi-stage lifting procedure. An example of this is described with respect to FIG. 13.

FIG. 13 shows an example of a parity check matrix 1316 of an LDPC code obtained by a two-stage lifting procedure.

In the first stage of the lifting procedure, the protograph matrix 502 is lifted to obtain an intermediate matrix 1306. The first stage involves replacing the zero entries of the protograph matrix 502 (e.g., the entries of the protograph matrix 502 that are equal to zero) with a 2×2 zero matrix. The first stage also involves replacing some of the non-zero entries with 2×2 circulant matrices and replacing other non-zero entries with lifting matrices that are based on the 2×2 Arikan kernel.

In particular, as indicated by the lifting indicator 1308 for the first stage, the (1,1) and (2,2) entries of the protograph matrix 502 are replaced in the first lifting stage with 2×2 circulant matrices with shifting values of 1 and 0 respectively. The (1,3) and (2,1) entries are replaced in the first lifting stage by column-wise shifts of the 2×2 Arikan kernel with shifting values of 1 and 0 respectively. The (1,2) and (2,3) entries are replaced by the 2×2 zero matrix. This results in the 4×6 intermediate matrix 1306 shown in FIG. 13.

In the second stage of the lifting procedure, the intermediate matrix 1306 is lifted to obtain the parity check matrix 1316. The second stage involves replacing the zero entries of the intermediate matrix 1306 (e.g., the entries of the intermediate matrix 1306 that are equal to zero) with a 3×3 zero matrix. The second stage also involves replacing some of the non-zero entries of the intermediate matrix 1306 with 3×3 circulant matrices and replacing the other non-zero entries of the intermediate matrix 1306 with lifting matrices that are based on the 3×3 Arikan kernel. The lifting indicator 1318 indicates which matrix is to replace each entry in the intermediate matrix 1306. A value of −1 in the lifting indicator 1318 indicates that the corresponding entry is to be replaced by a 3×3 zero matrix. A value containing a “p” and a number indicates that corresponding entry is to be replaced by a circularly shifted 3×3 polar kernel that has been shifted by that number of columns. A value containing a “c” and a number indicates that corresponding entry is to be replaced by a circularly shifted 3×3 identity matrix (e.g., a circulant matrix) that has been shifted by that number of columns.

Lifting the protograph matrix 502 to obtain the intermediate matrix 1306 and lifting the intermediate matrix 1306 to obtain the parity check matrix 1316 results in a 12×18 parity check matrix.

The lifting procedure shown in FIG. 13 is an example of a multi-step hybrid lifting method which simultaneously uses both polarized lifting and the circulant lifting in each step. This creates more flexibility in the generation of LDPC parity-check matrices.

According to the present disclosure, the parity check matrix of an LDPC code may be obtained by lifting a protograph matrix based on a polar kernel. Various example methods for lifting a protograph matrix have been provided, including lifting a protograph matrix using an Arikan kernel, a shortened Arikan kernel, a circular shifted Arikan kernel and/or a circular shifted shortened Arikan kernel. Hybrid lifting has also been provided, in which polarized lifting (e.g., lifting based on a polar kernel) and circulant-matrix based lifting are both used to lift a protograph matrix. This may be performed in the same stage, or as part of a multi-stage lifting procedure.

The present disclosure also provides a lifting indicator, which may also be referred to as an indicator matrix, which indicates which type of lifting is used for each entry of the protograph matrix. In some cases, the lifting indicator may represent, or may itself be known as, the protograph matrix or the intermediate matrix.

The present disclosure also provides a lifting sequence for multi-stage lifting procedures to indicate which type of lifting is used in each stage. As described above, the lifting sequence may comprise a binary sequence, for example.

FIG. 14 shows a flowchart of a method 1400 according to embodiments of the disclosure. The method 1400 is performed by an apparatus comprising an encoder and an interface.

The method involves, in step 1402, the encoder encoding input bits.

The encoder may, for example, comprise a processor which, when executing instructions (e.g., instructions stored in a memory of the apparatus), is caused to encode the input bits. In other examples, other implementations of the encoder may be used. In general, the encoder may be configured to perform the operations of the encoder described herein. It will be appreciated that the features or functions of the encoder that are described herein may be implemented in any of various ways, such as in hardware, firmware, or one or more components that execute software. The present disclosure is not limited to any specific type of implementation of the encoder, and implementation details may vary between different apparatus, for example.

The encoder encodes the input bits by an LDPC code to obtain encoded bits. The inputs bits may comprise information to be communicated. For example, the input bits may comprise data and/or control information. In some examples, the input bits may have already been encoded. The method 1400 may form part of a concatenated coding scheme, in which initial bits are encoded by an outer code to obtain the input bits and the input bits are encoded by the LDPC code in step 1402. In these example, the LDPC code may be referred to as an inner code. The input bits may comprise the initial bits and one or more coded bits (e.g., parity check bits). The outer code may be any suitable error-correcting code such as, for example, a Bose-Chaudhuri-Hocquenghem code (BCH) or a polar code.

The LDPC code has a parity check matrix obtained by lifting a protograph matrix according to a lifting matrix. The protograph matrix may be any matrix from which the parity check matrix can be constructed; accordingly, the protograph matrix may also include the intermediate matrix and the lifting indicator matrix discussed above. While the intermediate matrix and the lifting indicator matrix are described separately from the protograph matrix for ease of understanding the various examples herein, those matrices may be considered to be a type of protograph matrix because they each may be lifted to form a parity check matrix.

In some examples, the protograph matrix may be a submatrix of a larger matrix. Thus, the protograph matrix may comprise one or more rows and columns extracted from the larger matrix. The number of rows and columns extracted from the larger matrix may be based on a target (e.g., desired) code rate (e.g., as part of modulation and coding scheme adaptation). To achieve a higher code rate, fewer rows of the larger matrix may be selected (e.g., resulting in a smaller protograph matrix). To achieve a lower code rate, more rows of the larger matrix may be selected (e.g., resulting in a larger protograph matrix).

In some examples, entries (e.g., each entry) of the protograph matrix may have either a first value (e.g., 0) or a second value (e.g., 1), with the first value indicating that the respective entry is to be replaced by a zero matrix and the second value indicating that the respective entry is to be replaced by a respective lifting matrix (e.g., by the lifting matrix or a different matrix).

The lifting matrix is based on a polar kernel. The lifting matrix may be any of the lifting matrices referred to above in respect of FIGS. 7-13. The lifting matrix may comprise (e.g., be) the polar kernel. Alternatively, the lifting matrix may comprise (e.g., be) a circular shift of a polar kernel, which may also be referred to as a circularly shifted polar kernel. The circular shift of the polar kernel may be column-wise or row-wise. The polar kernel may comprise (e.g., may be) an Arikan kernel or a full rank submatrix of an Arikan kernel (e.g., a shortened polar kernel). The polar kernel may be any of the polar kernels described above in Equations (3)-(5) and in respect of FIGS. 7-13.

As described above in respect of FIGS. 7 and 8, there are two approaches for lifting a protograph matrix. Thus, lifting the protograph matrix according to the lifting matrix may have involved replacing a first entry in the protograph matrix having the first value with the lifting matrix and replacing a second entry in the protograph matrix having the second value with a zero matrix that has the same dimensions as the lifting matrix. In some examples, each entry in the protograph matrix that has the first value may be replaced with the lifting matrix (e.g., with the same lifting matrix). Examples of this are described in the generation of the parity check matrices 706a and 806a in the description of FIGS. 7 and 8 above. In other examples, different lifting matrices may be used for different entries in the protograph matrix, even when they have the same value (e.g., as in the examples described in FIGS. 9-12).

Alternatively, lifting the protograph matrix according to the lifting matrix may have involved replacing a first entry in the lifting matrix having a first value with the protograph matrix and replacing a second entry in the lifting matrix having a second value with a second zero matrix that has same dimensions as the protograph matrix. For example, each entry in the lifting matrix that has the first value may be replaced with the protograph matrix. Examples of this are described in the generation of the parity check matrices 706b and 806b in the description of FIGS. 7 and 8 above.

In some examples, the parity check matrix may have been obtained by replacing a first entry in the protograph matrix with the lifting matrix and replacing a second entry in the protograph matrix with a first circulant matrix comprising a permutation of a first identity matrix. The first entry and the second entry may have the same value (e.g., may be equal to 1, as in the examples described in respect of FIGS. 12 and 13). Other entries in the protograph matrix that have a different value (e.g., may be equal to 0) may be replaced by a zero matrix having the same dimensions as the lifting matrix and the first circulant matrix. This is an example of hybrid lifting, which involves both polarized lifting and circulant matrix-based lifting.

In some examples, lifting the protograph matrix may involve lifting the protograph matrix to obtain an intermediate matrix and lifting the intermediate matrix. Lifting the intermediate matrix may result in the parity check matrix (e.g., in a two-stage lifting procedure). Alternatively, lifting the intermediate matrix may result in another intermediate matrix (e.g., in a lifting procedure that involves 3 or more stages). Each lifting stage may be based the same or different lifting matrices. At least one lifting stage is based on a polar kernel.

For example, the method 1400 may involve lifting the protograph matrix according to the lifting matrix to obtain the intermediate matrix and lifting the intermediate matrix according to a second circulant matrix that comprises a permutation of a second identity matrix. In an alternative example, the method 1400 may involve lifting the protograph matrix according to the second circulant matrix to obtain the intermediate matrix and lifting the intermediate matrix according to the lifting matrix.

In some examples, one or more of the lifting stages may involve both polarized lifting and circulant matrix-based lifting. An examples of this is described above in respect of FIG. 13.

In step 1404, the method 1400 involves outputting, using the interface, the encoded bits.

Outputting the encoded bits may involve outputting the encoded bits to another apparatus using the interface. The interface may, for example, comprise a transmitter (e.g., any of the transmitters 201, 252, 272) coupled to one or more antennas (e.g., any of the one or more antennas 204, 256, 280) to transmit the encoded bits as a wireless transmission. The interface may additionally comprise a receiver (e.g., any of the receivers 203, 254, 274) for receiving wireless transmissions. The transmitter and the receiver may be connected to the same antenna. The transmitter and the receiver may be integrated (e.g., in a transceiver).

In some examples, step 1404 may involve transmitting the encoded bits from a communication device (e.g., the communication device described below) to another communication device in a wireless communication network. The other communication device may be, for example, a TRP or an electronic device. The other communication device may be configured to perform the method 1500 described below.

Alternatively, outputting the encoded bits may involve outputting the encoded bits, from the encoder, to another component of the apparatus using the interface. In some examples, the interface may comprise a bus interface for connecting the encoder to the other component of the apparatus via a bus of the apparatus. The other component may be any suitable component of the apparatus, such as a memory (e.g., any of the memories 208, 258, 278) of the apparatus. For example, outputting the encoded bits may involve the encoder outputting the encoded bits, via the interface, to a memory of the apparatus (e.g., for storage).

In some examples, step 1404 may involve the encoder outputting the encoded bits to another component of the apparatus for transmission (e.g., to another apparatus). For example, the encoder may output the encoded bits to a transmitter of the apparatus.

In other examples, step 1404 may involve the encoder outputting the encoded bits to another component of the apparatus for processing. For example, the method 1400 may form part of a concatenated coding scheme, in which the input bits are encoded by the LDPC code in step 1402 and then output, in step 1404 to an inner encoder for further encoding. Thus, step 1404 may involve outputting the encoded bits for encoding by an inner code (e.g., by another encoder). The inner code may be any suitable error correcting code such as, for example, a BCH code (e.g., a high-rate BCH code), a turbo code, a polar code or another LDPC code.

The method 1400 may further involve obtaining the LDPC code (e.g., the parity check matrix or a generator matrix of the LDPC code) used in step 1402 to encode the input bits. The LDPC code may be retrieved from a memory in the apparatus. The LDPC code may be received from another component in the apparatus (e.g., from a processor). Alternatively, the LDPC code may be received from another apparatus (e.g., from a communication device).

In some examples, the method 1400 may involve determining the LDPC code by lifting the protograph matrix (e.g., using the approaches described above). For example, a processor of the apparatus may lift the protograph matrix to determine the parity check matrix of the LDPC code. The processor may output the LDPC code to the encoder for use in step 1402.

The method 1400 may involve determining the LDPC code by performing any of the lifting described above in respect of step 1402 to obtain the parity check matrix. The method 1400 may involve determining the lifting matrix. The lifting matrix may be determined based on a target (e.g., a desired) code length (e.g., as part of modulation and coding scheme adaptation). That is, the size of the lifting matrix may be determined based on the target code length. To achieve a longer code, a larger lifting matrix may be used (e.g., a lifting matrix with more rows and columns). To achieve a shorter code, the smaller lifting matrix may be used (e.g., a lifting matrix with fewer rows and columns). Determining the lifting matrix may involve shortening an Arikan kernel to obtain a lifting matrix of the desired size. Any suitable shortening technique may be used including, for example, bit-reversed shortening, reverse shortening, etc.

As described above, lifting the protograph matrix may involve lifting one or more entries of the protograph matrix with respective lifting matrices. The method 1400 may involve lifting the protograph matrix according to a lifting indicator, in which the lifting indicator indicates which matrix is to replace each entry in the protograph matrix. In the example described above in which lifting the protograph matrix involves replacing the first entry in the protograph matrix with the lifting matrix and replacing the second entry in the protograph matrix with the first circulant matrix, the lifting indicator may indicate that the first entry is to be replaced by the lifting matrix and the second entry is to be replaced by first circulant matrix.

The lifting indicator may be as described above in respect of FIGS. 9-13. For example, the lifting indicator may comprise any of the lifting indicators 908, 1008, 1108, 1118, 1208a, 1208b, 1208c, 1208d, 1308 or 1318. In some examples, determining the LDPC code may involve lifting the protograph matrix in two or more stages, in which each of the two or more stages involves lifting according to a respective lifting indicator.

The lifting indicator may be determined by the apparatus (e.g., by a processor of the apparatus). Alternatively, the lifting indicator may be received from another apparatus (e.g., from a communication device such as TRP or electronic device).

In the above description of the method 1400, the method 1400 is described as being performed by an apparatus comprising an encoder and an interface. The apparatus may comprise a communication device in a wireless communications network. The communication device may comprise, for example, a TRP (e.g., may be a network node or base station), such as any of the TRPs 170 described above in respect of FIGS. 1-4) or an electronic device, such as any of the electronic devices 110 described above in respect of FIGS. 1-4. The wireless communications network may comprise a radio access network, such as the radio access network 120, for example.

The apparatus may comprise a robot, a sensor (e.g., a sensing device or apparatus), a vehicle (e.g., a car), an unmanned aerial vehicle (e.g., a drone) or a satellite. The apparatus may be configured to provide any suitable services such as, for example, enhanced mobile broadband (eMBB), ultra-reliable low latency communications (URLLC), massive machine type communications (mMTC), internet of things (IoT), vehicular services (e.g., vehicle-to-vehicle communications), and/or industry scenarios.

In some embodiments, the apparatus may be configured to perform the method 1400 (e.g., even if the apparatus does not comprise the encoder and/or the interface). The apparatus may comprise a processor configured to cause the apparatus to perform the method 1400, for example.

The apparatus (e.g., the communication device) may comprise a processor, a transmitter, an antenna and a memory (e.g., in addition to, or instead of the encoder and/or the interface). The apparatus may further comprise a receiver. Alternatively, the apparatus may comprise a transceiver instead of the transmitter and the receiver. The processor may implement various operations of the apparatus, including the steps of the method 1400. The processor may include any suitable processing or computing device configured to perform the one or more operations. The processor could, for example, include a microprocessor, microcontroller, digital signal processor, field programmable gate array or application specific integrated circuit.

In some examples, one or more steps of the method 1400 may be performed by more than one apparatus (e.g., may be distributed across one or more apparatus).

FIG. 15 shows a flowchart of a method 1500 according to embodiments of the disclosure. The method 1500 is performed by an apparatus comprising a decoder and an interface.

The method involves, in step 1502, receiving, using the interface, encoded bits encoded by a LDPC code.

The LDPC code has a parity check matrix obtained by lifting a protograph matrix according to a lifting matrix. The lifting matrix is based on a polar kernel. The encoded bits may have been encoded as described above in the method 1400.

Receiving the encoded bits may involve receiving the encoded bits from another apparatus using the interface. The interface may, for example, comprise a receiver (e.g., any of the receivers 203, 254, 274) coupled to one or more antennas (e.g., any of the one or more antennas 204, 256, 280) to transmit the encoded bits as a wireless transmission. The interface may additionally comprise a transmitter (e.g., any of the transmitters 201, 252, 272) for transmitting wireless transmissions. The transmitter and the receiver may be connected to the same antenna. The transmitter and the receiver may be integrated (e.g., in a transceiver).

In some examples, step 1502 may involve receiving the encoded bits by a communication device (e.g., the communication device described below) from another communication device in a wireless communication network. The other communication device may be, for example, a TRP or an electronic device. The other communication device may be configured to perform the method 1400 described above.

Alternatively, receiving the encoded bits may involve receiving the encoded bits from another component of the apparatus using the interface. In some examples, the interface may comprise a bus interface for connecting the encoder to another component of the apparatus via a bus of the apparatus. The other component may be any suitable component of the apparatus, such as a memory (e.g., any of the memories 208, 258, 278) of the apparatus. For example, the encoded bits may be retrieved from a memory of the apparatus. In another example, the encoded bits may be received from a receiver of the apparatus via the interface.

In another example, step 1502 may involve the decoder receiving the encoded bits from another decoder. As mentioned above, the LDPC codes as described herein may be implemented as an inner code or an outer code of a concatenated decoding scheme, in which input bits are first encoded by an outer code and then the intermediate encoded bits are encoded by the outer code to obtain the encoded bits. Thus, the step 1502 may involve receiving the encoded bits from an inner decoder (e.g., the decoder of the apparatus may be an outer decoder). The inner decoder may be any suitable decoder of error correcting codes.

In step 1504, the decoder decodes the encoded bits to obtain decoded input bits.

The decoder may, for example, comprise a processor which, when executing instructions (e.g., instructions stored in a memory of the apparatus), is caused to decode the encoded bits. In other examples, other implementations of the decoder may be used. In general, the decoder may be configured to perform the operations of the decoder described herein. It will be appreciated that the features or functions of the decoder that are described herein may be implemented in any of various ways, such as in hardware, firmware, or one or more components that execute software. The present disclosure is not limited to any specific type of implementation of the decoder, and implementation details may vary between different apparatus, for example.

The decoder may decode the encoded bits using a belief propagation procedure. Any suitable belief propagation procedure may be used such as, for example, flooding belief propagation, layered belief propagation etc.

As the encoded bits were encoded using an LDPC code that was obtained by lifting a protograph matrix based on a polar kernel, the decoding in step 1504 may convergence more quickly because the structure of the resulting LDPC code encourages directional mutual information flow during decoding, thereby improving the convergence speed and decoding efficiency of the LDPC code. This advantage may be achieved even when existing decoding techniques are used.

The method 1500 may further involve outputting the decoded input bits. For example, the decoder may output the decoded input bits to another apparatus (e.g., another communication device as described in more detail below). In other examples, the decoder may output the decoded input bits to another component of the apparatus. For example, the decoder may output the decoded input bits to a processor (e.g., for processing). In another example, the decoder may output the decoded input bits to a memory (e.g., for storage).

In other examples, the method 1500 may involve the decoder outputting the decoded input bits to another component of the apparatus for further decoding. For example, LDPC code may be an inner code of a concatenated decoding scheme, in which input bits are first encoded by an outer code and then the intermediate encoded bits are encoded by the LDPC code to obtain the encoded bits. Thus, the decoder may be an inner decoder. The method 1500 may also involve outputting the decoded input bits to another decoder (e.g., an outer decoder) further decoding. The outer decoder may be any suitable decoder of error correcting codes.

In the above description of the method 1500, the method 1500 is described as being performed by an apparatus comprising a decoder and an interface. The apparatus may comprise a communication device in a wireless communications network. The communication device may comprise, for example, a TRP (e.g., may be a network node or base station), such as any of the TRPs 170 described above in respect of FIGS. 1-4) or an electronic device, such as any of the electronic devices 110 described above in respect of FIGS. 1-4. The wireless communications network may comprise a radio access network, such as the radio access network 120, for example.

The apparatus may comprise a robot, a sensor (e.g., a sensing device or apparatus), a vehicle (e.g., a car), an unmanned aerial vehicle (e.g., a drone) or a satellite. The apparatus may be configured to provide any suitable services such as, for example, enhanced mobile broadband (eMBB), ultra-reliable low latency communications (URLLC), massive machine type communications (mMTC), internet of things (IoT), vehicular services (e.g., vehicle-to-vehicle communications), and/or industry scenarios.

In some embodiments, the apparatus may be configured to perform the method 1500 (e.g., even if the apparatus does not comprise the encoder and/or the interface). The apparatus may comprise a processor configured to cause the apparatus to perform the method 1500, for example.

The apparatus may comprise a processor, a receiver, an antenna and a memory. The apparatus may further comprise a transmitter. Alternatively, the apparatus may comprise a transceiver instead of the transmitter and the receiver. The processor may implement various operations of the apparatus, including the steps of the method 1500. The processor may include any suitable processing or computing device configured to perform the one or more operations. The processor could, for example, include a microprocessor, microcontroller, digital signal processor, field programmable gate array or application specific integrated circuit.

In some examples, one or more steps of the method 1500 may be performed by more than one apparatus (e.g., may be distributed across one or more apparatus).

It should be appreciated that one or more steps of the embodiment methods provided herein may be performed by corresponding units or modules. For example, a signal may be transmitted by a transmitting unit or a transmitting module. A signal may be received by a receiving unit or a receiving module. A signal may be processed by a processing unit or a processing module. The respective units/modules may be hardware, software, or a combination thereof. For instance, one or more of the units/modules may be an integrated circuit, such as field programmable gate arrays (FPGAs) or application-specific integrated circuits (ASICs). It will be appreciated that where the modules are software, they may be retrieved by a processor, in whole or part as needed, individually or together for processing, in single or multiple instances as required, and that the modules themselves may include instructions for further deployment and instantiation.

Although a combination of features is shown in the illustrated embodiments, not all of them need to be combined to realize the benefits of various embodiments of this disclosure. In other words, a system or method designed according to an embodiment of this disclosure will not necessarily include all of the features shown in any one of the figures or all of the portions schematically shown in the figures. Moreover, selected features of one example embodiment may be combined with selected features of other example embodiments.

While this disclosure has been described with reference to illustrative embodiments, this description is not intended to be construed in a limiting sense. Numerous modifications and variations of the present disclosure are possible in light of the above teachings. It is therefore to be understood that within the scope of the appended claims, the disclosure may be practiced otherwise than as specifically described herein.

1. A method comprising:
encoding input bits by a low density parity check (LDPC) code to obtain encoded bits, the LDPC code having a parity check matrix obtained by lifting a protograph matrix according to a lifting matrix, wherein the lifting matrix is based on a polar kernel; and
outputting the encoded bits.

2. The method of claim 1, wherein the parity check matrix is obtained by replacing a first entry in the protograph matrix with the lifting matrix and replacing a second entry in the protograph matrix with a first circulant matrix comprising a permutation of a first identity matrix.

3. The method of claim 1, wherein the lifting the protograph matrix according to the lifting matrix comprises:
replacing a first entry in the protograph matrix having a first value with the lifting matrix and replacing a second entry in the protograph matrix having a second value with a first zero matrix having same dimensions as the lifting matrix; or
replacing a first entry in the lifting matrix having a first value with the protograph matrix and replacing a second entry in the lifting matrix having a second value with a second zero matrix that has same dimensions as the protograph matrix.

4. The method of claim 1, wherein the parity check matrix is obtained by:
lifting the protograph matrix according to one of the lifting matrix or a second circulant matrix to obtain an intermediate matrix, the second circulant matrix comprising a permutation of a second identity matrix; and
lifting the intermediate matrix according to the other one of the lifting matrix or the second circulant matrix.

5. The method of claim 1, wherein the polar kernel comprises an Arikan kernel or a full rank submatrix of the Arikan kernel.

6. A method comprising:
receiving encoded bits encoded by a low density parity check (LDPC) code, the LDPC code having a parity check matrix obtained by lifting a protograph matrix according to a lifting matrix, wherein the lifting matrix is based on a polar kernel; and
decoding the encoded bits to obtain decoded input bits.

7. The method of claim 6, wherein the parity check matrix is obtained by replacing a first entry in the protograph matrix with the lifting matrix and replacing a second entry in the protograph matrix with a first circulant matrix comprising a permutation of a first identity matrix.

8. The method of claim 6, wherein the lifting the protograph matrix according to the lifting matrix comprises:
replacing a first entry in the protograph matrix having a first value with the lifting matrix and replacing a second entry in the protograph matrix having a second value with a first zero matrix having same dimensions as the lifting matrix; or
replacing a first entry in the lifting matrix having a first value with the protograph matrix and replacing a second entry in the lifting matrix having a second value with a second zero matrix that has same dimensions as the protograph matrix.

9. The method of claim 6, wherein the parity check matrix is obtained by:
lifting the protograph matrix according to one of the lifting matrix or a second circulant matrix to obtain an intermediate matrix, the second circulant matrix comprising a permutation of a second identity matrix; and
lifting the intermediate matrix with the other one of the lifting matrix and the second circulant matrix.

10. The method of claim 6, wherein the polar kernel comprises an Arikan kernel or a full rank submatrix of the Arikan kernel.

11. An apparatus comprising:
at least one processor; and
a memory coupled to the at least one processor, the memory storing instructions that, when executed by the at least one processor, cause the apparatus to:
encode input bits by a low density parity check (LDPC) code to obtain encoded bits, the LDPC code having a parity check matrix obtained by lifting a protograph matrix according to a lifting matrix, wherein the lifting matrix is based on a polar kernel; and
output the encoded bits.

12. The apparatus of claim 11, wherein the parity check matrix is obtained by replacing a first entry in the protograph matrix with the lifting matrix and replacing a second entry in the protograph matrix with a first circulant matrix comprising a permutation of a first identity matrix.

13. The apparatus of claim 11, wherein the lifting the protograph matrix according to the lifting matrix comprises:
replacing a first entry in the protograph matrix having a first value with the lifting matrix and replacing a second entry in the protograph matrix having a second value with a first zero matrix having same dimensions as the lifting matrix; or
replacing a first entry in the lifting matrix having a first value with the protograph matrix and replacing a second entry in the lifting matrix having a second value with a second zero matrix that has same dimensions as the protograph matrix.

14. The apparatus of claim 11, wherein the parity check matrix is obtained by:
lifting the protograph matrix according to one of the lifting matrix or a second circulant matrix to obtain an intermediate matrix, the second circulant matrix comprising a permutation of a second identity matrix; and
lifting the intermediate matrix according to the other one of the lifting matrix or the second circulant matrix.

15. The apparatus of claim 11, wherein the polar kernel comprises an Arikan kernel or a full rank submatrix of the Arikan kernel.

16. A apparatus comprising:
at least one processor; and
a memory coupled to the at least one processor, the memory storing instructions that, when executed by the at least one processor, cause the apparatus to:
receive encoded bits encoded by a low density parity check (LDPC) code, the LDPC code having a parity check matrix obtained by lifting a protograph matrix according to a lifting matrix, wherein the lifting matrix is based on a polar kernel; and
decode the encoded bits to obtain decoded input bits.

17. The apparatus of claim 16, wherein the parity check matrix is obtained by replacing a first entry in the protograph matrix with the lifting matrix and replacing a second entry in the protograph matrix with a first circulant matrix comprising a permutation of a first identity matrix.

18. The apparatus of claim 16, wherein the lifting the protograph matrix according to the lifting matrix comprises:
replacing a first entry in the protograph matrix having a first value with the lifting matrix and replacing a second entry in the protograph matrix having a second value with a first zero matrix having same dimensions as the lifting matrix; or
replacing a first entry in the lifting matrix having a first value with the protograph matrix and replacing a second entry in the lifting matrix having a second value with a second zero matrix that has same dimensions as the protograph matrix.

19. The apparatus of claim 16, wherein the parity check matrix is obtained by:
lifting the protograph matrix according to one of the lifting matrix or a second circulant matrix to obtain an intermediate matrix, the second circulant matrix comprising a permutation of a second identity matrix; and
lifting the intermediate matrix with the other one of the lifting matrix or the second circulant matrix.

20. The apparatus of claim 16, wherein the polar kernel comprises an Arikan kernel or a full rank submatrix of the Arikan kernel.
